(19) United States
(12) Patent Application Publication
(10) Pub. No.: US 2026/0239529 A1
(43) Pub. Date: Aug. 13, 2026

(54) PRINTED CIRCUIT BOARD

(71) Applicant: SAMSUNG ELECTRO-MECHANICS CO., LTD., Suwon-si (KR)

(72) Inventors: Hyuck CHOO, Suwon-si (KR); Tae Hong MIN, Suwon-si (KR); Ki Suk KIM, Suwon-si (KR)

(73) Assignee: SAMSUNG ELECTRO-MECHANICS CO., LTD., Suwon-si (KR)

(21) Appl. No.: 19/408,585

(22) Filed: Dec. 4, 2025

(30) Foreign Application Priority Data
Feb. 7, 2025 (KR) 10-2025-0015859
Jun. 19, 2025 (KR) 10-2025-0081010

(51) Int. Cl. H05K 1/02; H05K 1/03; H05K 1/11; H05K 1/183

(52) U.S. Cl. CPC H05K 1/0298; H05K 1/0306; H05K 1/115; H05K 1/183; H05K 2201/2081

(57) ABSTRACT

The present disclosure relates to a printed circuit board including: a glass layer; a first wiring portion disposed on the glass layer; and a second wiring portion disposed on the first wiring portion. The first wiring portion includes one or more inorganic insulating layers, one or more first wiring layers respectively disposed on or within the one or more inorganic insulating layers, and one or more first wiring vias respectively disposed within the one or more inorganic insulating layers. The second wiring portion includes one or more first organic insulating layers, one or more second wiring layers respectively disposed on or within the one or more first organic insulating layers, and one or more second wiring vias respectively disposed within the one or more first organic insulating layers. The second wiring portion has a cavity penetrating through at least a portion of the one or more first organic insulating layers.

### CROSS-REFERENCE TO RELATED APPLICATION(S)

This application claims benefit of priority to Korean Patent Application Nos. 10-2025-0015859 and 10-2025-0081010 filed on February 7, 2025, and June 19, 2025, respectively, in the Korean Intellectual Property Office, the disclosures of which are incorporated herein by reference in their entirety.

### TECHNICAL FIELD

The present disclosure relates to a printed circuit board.

The recent surge in demand for high-performance computing and large-scale data processing has led to a rapid expansion of the server-centric semiconductor application market. In response, demand for large-area substrates for high-density and high-bandwidth processing has increased, and this, in turn, is driving continued miniaturization and performance enhancements in substrates and packages. For example, with the growing demand for chiplets and heterogeneous integrated packages, which integrate a plurality of chips within a single package to implement distributed functions, the importance of reducing a gap between fine wiring lines, ensuring overall package and substrate flatness, and controlling warpage has grown. However, existing substrate technologies using organic-based copper-clad laminates (CCL) face limitations in terms of pitch reduction and warpage control.

### SUMMARY

An aspect of the present disclosure is to provide a printed circuit board that may be applied to large-area products, may allow for miniaturization and the implementation of high performance, and may have an advantageous structure in terms of pitch reduction and warpage control.

One of various solutions proposed through the present disclosure is to provide a printed circuit board by forming an inorganic insulating layer and a fine wiring layer on a glass layer having excellent flatness, and forming an organic insulating layer and a general wiring layer thereon, and forming, in this case, a cavity capable of being used as a mounting space for a semiconductor chip, in the organic insulating layer.

For example, a printed circuit board according to an example embodiment may include: a glass layer; a first wiring portion disposed on an upper side of the glass layer; and a second wiring portion disposed on an upper side of the first wiring portion, and the first wiring portion may include one or more inorganic insulating layers, one or more first wiring layers respectively disposed on or within the one or more inorganic insulating layers, and one or more first wiring vias respectively disposed within the one or more inorganic insulating layers, and the second wiring portion may include one or more first organic insulating layers, one or more second wiring layers respectively disposed on or within the one or more first organic insulating layers, and one or more second wiring vias respectively disposed within the one or more first organic insulating layers, and has a cavity penetrating through at least a portion of the one or more first organic insulating layers.

For example, a printed circuit board according to an example embodiment may include: a glass layer; a first substrate portion disposed on an upper side of the glass layer; and a second substrate portion disposed on an upper side of the first substrate portion, the second substrate portion including a first region having a cavity in a planar plane and a second region surrounding the first region, and the first substrate portion may include a first insulating body including an inorganic insulating material and one or more first conductive pattern layers respectively disposed on or within the first insulating body, the second wiring portion may include a second insulating body including an organic insulating material and one or more second conductive pattern layers respectively disposed on or within the second insulating body, and the one or more second conductive pattern layers may be disposed in the second region.

One of the various effects of the present disclosure is to form a printed circuit board structure that may be applied to large-area products, may enable miniaturization and high performance, and may be advantageous in terms of pitch reduction and warpage control.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic cross-sectional view of an example of a printed circuit board;

FIG. 2 is a schematic plan view of a top view of the printed circuit board of FIG. 1;

FIGS. 3A to 3F are process cross-sectional views schematically illustrating an example of manufacturing a printed circuit board;

FIG. 4 is a schematic cross-sectional view of a modified example of a printed circuit board;

FIG. 5 is a schematic cross-sectional view of another modified example of a printed circuit board;

FIG. 6 is a schematic cross-sectional view of another modified example of a printed circuit board;

FIG. 7 is a schematic cross-sectional view of another modified example of a printed circuit board;

FIG. 8 is a schematic cross-sectional view of another modified example of a printed circuit board;

FIG. 9 is a schematic cross-sectional view of another modified example of a printed circuit board;

FIG. 10 is a schematic cross-sectional view of another modified example of a printed circuit board;

FIG. 11 is a cross-sectional view schematically illustrating another example of a printed circuit board;

FIG. 12 is a plan view schematically illustrating a top view of the printed circuit board of FIG. 11;

FIGS. 13A and 13B are process cross-sectional views schematically illustrating another example of manufacturing a printed circuit board;

FIG. 14 is a cross-sectional view schematically illustrating a modified example of a printed circuit board;

FIG. 15 is a cross-sectional view schematically illustrating another modified example of a printed circuit board;

FIG. 16 is a cross-sectional view schematically illustrating another modified example of a printed circuit board;

FIG. 17 is a cross-sectional view schematically illustrating another modified example of a printed circuit board;

FIG. 18 is a cross-sectional view schematically illustrating another modified example of a printed circuit board;

FIG. 19 is a cross-sectional view schematically illustrating another modified example of a printed circuit board; and

FIG. 20 is a cross-sectional view schematically illustrating another modified example of a printed circuit board.

### DETAILED DESCRIPTION

Hereinafter, the present disclosure will be described with reference to the attached drawings. The shapes and sizes of elements in the drawings may be exaggerated or reduced for clearer explanation.

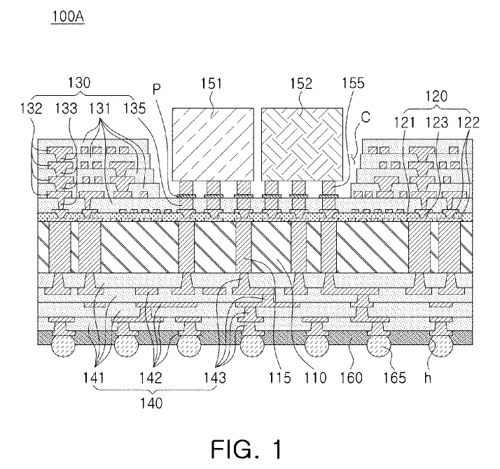

FIG. 1 is a schematic cross-sectional view of an example of a printed circuit board.

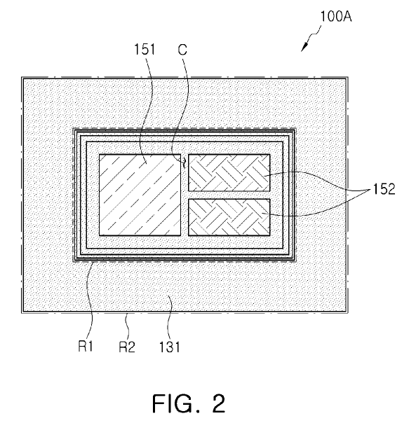

FIG. 2 is a schematic plan view of a top view of the printed circuit board of FIG. 1.

Referring to the drawings, a printed circuit board 100A according to an example embodiment may include a glass layer 110, a first wiring portion 120 disposed on an upper side of the glass layer 110, and a second wiring portion 130 disposed on an upper side of the first wiring portion 120. The first wiring portion 120 may include one or more inorganic insulating layers 121, one or more first wiring layers 122 disposed on or within the one or more inorganic insulating layers 121, and one or more first wiring vias 123 disposed within the one or more inorganic insulating layers 121. The second wiring portion 130 may include one or more first organic insulating layers 131, one or more second wiring layers 132 disposed on or within the one or more organic insulating layers 131, and one or more second wiring vias 133 disposed within the one or more first organic insulating layers 131. The second wiring portion 130 may have a cavity C penetrating through at least a portion of one or more first organic insulating layers 131.

In this manner, the printed circuit board 100A according to an example embodiment may include a glass layer 110 that has superior flatness and is advantageous for warpage control compared to an organic-based copper-clad laminate. Furthermore, the first wiring portion 120 including the one or more inorganic insulating layers 121, the one or more first wiring layers 122, and the one or more first wiring vias 123 may be formed on the glass layer 110. In this case, by utilizing flatness properties of the glass layer 110 and thin film properties of one or more inorganic insulating layers 121, the one or more first wiring layers 122 and the one or more first wiring vias 123 may be formed as fine wiring and fine vias, respectively. Accordingly, a silicon interposer or an interconnect bridge for die-to-die signal transmission may be replaced with the first wiring portion 120, and the first wiring portion 120 may also serve as other high-density wiring portions. Furthermore, the glass layer 110 may have higher thermal conductivity than the organic-based copper-clad laminate, thereby improving heat dissipation.

Furthermore, a printed circuit board 100A according to an example embodiment may form a second wiring portion 130 on the first wiring portion 120, including one or more first organic insulating layers 131, one or more second wiring layers 132 and one or more second wiring vias 133, and in this case, a cavity C penetrating through at least a portion of the one or more first organic insulating layers 131 may be formed in the second wiring portion 130. In this case, a plurality of semiconductor chips 151 and 152 may be mounted in the cavity C, as described below. Accordingly, a signal transmission path or a power transmission path between the first wiring portion 120 and the plurality of semiconductor chips 151 and 152 may be minimized. Furthermore, even when the plurality of semiconductor chips 151 and 152 are mounted, an overall thickness of the product may be reduced.

Furthermore, the printed circuit board 100A according to an example embodiment may have one or more second wiring layers 132 and one or more second wiring vias 133 disposed around the cavity C. For example, the second wiring portion 130 may have a first region R1 having the cavity C in a planar plane and a second region R2 surrounding the first region R1. The one or more second wiring layers 132 and the one or more second wiring vias 133 may be disposed in the second region R2. In this case, a rigid metal may be disposed around the cavity C in which the plurality of semiconductor chips 151 and 152 are disposed, thereby facilitating warpage control and improvement. Furthermore, various functions may be added to a substrate by forming capacitor patterns, inductor patterns, dummy patterns, and the like, on the second wiring portion 130. Furthermore, by forming a large number of power wiring lines on the second wiring portion 130, the number of layers of third wiring portion 140, described below, may be reduced. Additionally, the printed circuit board 100A may be applied to a package-on-package (PoP) structure via the second wiring portion 130.

Meanwhile, each of the one or more inorganic insulating layers 121 may include one or more of a silicon oxide film and a silicon nitride film. However, the present disclosure is not limited thereto, and, as described below, various other inorganic insulating materials used as materials for inorganic insulating films in semiconductor processes may also be used. When the one or more inorganic insulating layers 121 include such inorganic insulating materials, the one or more inorganic insulating layers 121 may be formed to have a thinner thickness. For example, a thickness of at least one of the one or more inorganic insulating layers 121 may be thinner than a thickness of at least one of the first organic insulating layers 131. The thickness of each of the one or more inorganic insulating layers 121 may be preferably thinner than the thickness of each of the one or more first organic insulating layers 131. Additionally, an overall thickness of one or more inorganic insulating layers 121 may be thinner than an overall thickness of one or more first organic insulating layers 131. For example, the thickness of each of the one or more inorganic insulating layers 121, for example, a height from a lower surface to an upper surface of each inorganic insulating layer 121, may be 5 μm or less, but the present disclosure is not limited thereto. For example, at least a portion of the one or more inorganic insulating layers 121 may be easily formed as a thin film.

Additionally, at least one of the one or more first wiring layers 122 may include a relatively high-density wiring line as compared to at least one of the one or more second wiring layers 132. Each of the one or more first wiring layers 122 may preferably include a relatively high-density wiring line as compared to each of the one or more second wiring layers 132. For example, a thickness of at least one of the one or more first wiring layers 122 may be thinner than a thickness of at least one of the one or more second wiring layers 132. The thickness of each of the one or more first wiring layers 122 may be preferably thinner than the thickness of each of the one or more second wiring layers 132. For example, each of the one or more first wiring layers 122 may include a plurality of line patterns, and in this case, a line width, a gap, and a thickness of the plurality of line patterns may each be 3 μm or less, but the present disclosure is not limited thereto. For example, at least a portion of the one or more first wiring layers 122 may be easily formed as a fine wiring line.

Furthermore, at least one of the one or more first wiring vias 123 may include a relatively high-density via as compared to at least one of the one or more second wiring vias 133. Each of the one or more first wiring vias 123 may preferably include a relatively high-density via as compared to each of the one or more second wiring vias 133. For example, the thickness of at least one of the one or more first wiring vias 123 may be thinner than the thickness of at least one of the one or more second wiring vias 133. The thickness of each of the one or more first wiring vias 123 may be preferably thinner than the thickness of each of the one or more second wiring vias 133. For example, at least some of the one or more first wiring vias 123 may be easily formed as micro-vias.

Referring to the drawings, the printed circuit board 100A according to an example embodiment may further include a third wiring portion 140 disposed on a lower side of the glass layer 110 and a through-via 115 penetrating through at least a portion of the glass layer 110. The third wiring portion 140 may further include one or more second organic insulating layers 141, one or more third wiring layers 142 disposed on or within the one or more second organic insulating layers 141, and one or more third wiring vias 143 disposed within the one or more second organic insulating layers 141. The second and third wiring portions 130 and 140 may have symmetrical layers, but the present disclosure is not limited and the second and third wiring portions 130 and 140 may also be asymmetrical. Here, the number of layers may be the number of first and second organic insulating layers 131 and 141 and/or second and third wiring layers 132 and 142 included in each of the second and third wiring portions 130 and 140.

For example, in a printed circuit board 100A according to an example embodiment, the first and second wiring portions 120 and 130 and the third wiring portion 140 may be disposed on an upper side and a lower side of the glass layer 110, respectively, which may allow for a wider variety of wiring designs. Furthermore, warpage control may be facilitated. The through-via 115 may include a Through-Glass Via (TGV) and may electrically connect the first and third wiring portions 120 and 140 to each other. For example, the one or more of the first and third wiring layers 122 and 142 may be electrically connected to each other. Furthermore, the through-via 115 may have a smaller pitch than a through-via formed on the organic-based copper-clad laminate, thereby improving power integrity. Meanwhile, the glass layer 110 may be used as a core layer. For example, the glass layer 110 may be a glass core.

Meanwhile, a first wiring layer 122 of a lowermost layer, among the one or more first wiring layers 122, may be in direct contact with an upper surface of the glass layer 110. On the other hand, a third wiring layer 142 of an uppermost layer, among the one or more third wiring layers 142, may be spaced apart from a lower surface of the glass layer 110. In this case, a second organic insulating layer 141 of an uppermost layer, among the one or more second organic insulating layers 141, may be disposed between the lower surface of the glass layer 110 and the third wiring layer 142 of the uppermost layer. For example, the lowermost layer of the first wiring layers 122 requiring a relatively high-density wiring design may be formed directly on an upper surface of the glass layer 110 having excellent flatness. On the other hand, the uppermost layer of the third wiring layers 142, sufficient for a relatively low-density wiring design, may be formed on a lower surface of the uppermost layer of the second organic insulating layers 141 to secure adhesion. From this perspective, an upper surface of the through-via 115 may be in direct contact with and connected to at least a portion of the lowermost layer of the first wiring layers 122. Conversely, a lower surface of the through-via 115 may be connected to at least a portion of the uppermost layer of the third wiring layers 142, through one or more third wiring vias 143 penetrating through at least a portion of a second organic insulating layer 141 of an uppermost layer, among the one or more third wiring vias 143. In the present disclosure, the one or more layers may be one layer or a plurality of layers, and in the case of one layer, the uppermost and lowermost layers may be identical, while in the case of a plurality of layers, the uppermost and lowermost layers may be distinct from each other.

Furthermore, the thickness of at least one of the one or more inorganic insulating layers 121 may be thinner than a thickness of at least one of the second organic insulating layers 141. The thickness of each of the one or more inorganic insulating layers 121 may be preferably thinner than the thickness of each of the one or more second organic insulating layers 141. Additionally, an overall thickness of the one or more inorganic insulating layers 121 may be thinner than an overall thickness of the one or more second organic insulating layers 141. Additionally, at least one of the one or more first wiring layers 122 may include a relatively higher density of wiring line than at least one of the one or more third wiring layers 142. Each of the one or more first wiring layers 122 may preferably include a relatively higher density of wiring line than each of the one or more third wiring layers 142. For example, the thickness of at least one of the one or more first wiring layers 122 may be thinner than a thickness of at least one of the one or more third wiring layers 142. The thickness of each of the one or more first wiring layers 122 may be preferably thinner than the thickness of each of the one or more third wiring layers 142. Additionally, at least one of the one or more first wiring vias 123 may include a relatively higher density of vias than at least one of the one or more third wiring vias 143. Each of the one or more first wiring vias 123 may preferably include a relatively high-density via as compared to each of the one or more third wiring vias 143. For example, a thickness of at least one of the one or more first wiring vias 123 may be thinner than a thickness of at least one of the one or more third wiring vias 143. The thickness of each of the one or more first wiring vias 123 may be preferably thinner than the thickness of each of the one or more third wiring vias 143. In this case, the technical effects described above may be more easily achieved.

Referring to the drawings, in the printed circuit board 100A according to an example embodiment, one or more first wiring layers 122, one or more second wiring layers 132, and one or more third wiring layers 142 may include a plurality of first wiring layers 122, a plurality of second wiring layers 132, and a plurality of third wiring layers 142, respectively. Additionally, the one or more first wiring vias 123, the one or more second wiring vias 133, and the one or more third wiring vias 143 may include a plurality of first wiring vias 123, a plurality of second wiring vias 133 and a plurality of third wiring vias 143, respectively. Furthermore, the one or more inorganic insulating layers 121 may be a single inorganic insulating layer 121, and the one or more organic first organic insulating layers 131 and one or more second organic insulating layers 141 may include a plurality of first organic insulating layers 131 and a plurality of second organic insulating layers 141, respectively.

For example, in the printed circuit board 100A according to an example embodiment, each of the first to third wiring portions 120, 130 and 140 may be configured as multilayer structures. In this case, each of the plurality of second wiring layers 132 and the plurality of third wiring layers 142 may have a greater number of layers than the plurality of first wiring layers 122. For example, the plurality of first wiring layers 122 may be layers in which signal regions for die-to-die signal transmission, and the like, are formed at high density, while the plurality of second and third wiring layers 132 and 142 may be layers in which a power region, a ground region, a dummy region, and the like, are formed, and thus, the number of layers may differ, relative to each other. From this perspective, the first wiring portion 120 may include a single inorganic insulating layer 121, while each of the second and third wiring portions 130 and 140 may include a plurality of first and second organic insulating layers 131 and 141. However, the number of layers of the first to third wiring portions 120, 130 and 140 is not necessarily limited thereto, and for example, each of the first to third wiring layers 122, 132 and 142 and the first and second organic insulating layers 131 and 141 do not necessarily need to be a plurality of layers. For example, at least one of the first and second organic insulating layers 131 and 141 may be a single layer, if necessary. Furthermore, at least one of the first to third wiring layers 122, 132 and 142 may be a single layer, if necessary.

Meanwhile, the first to third wiring portions 120, 130 and 140 may be referred to as the first to third substrate portions 120, 130 and 140 depending on the purpose, function, effect, and the like, of each component. Additionally, the first to third wiring layers 122, 132 and 142 may be referred to as first to third conductive pattern layers 122, 132 and 142 depending on the purpose, function, effect, and the like, of each component. Additionally, the first to third wiring vias 123, 133 and 143 may be referred to as first to third conductive vias 123, 133 and 143 depending on the purpose, function, effect, and the like, of each component. For example, the terms used in the present disclosure may be interchangeably used depending on the structure, function, or common understanding in the general technical field of the component, which should not be construed as limiting the scope of protection of the invention.

Referring to the drawings, in a printed circuit board 100A according to an example embodiment, the second wiring portion 130 may further include a plurality of conductive bumps 135 respectively penetrating through at least one of the one or more first organic insulating layers 131, for example, at least a portion of a first organic insulating layer 131 of a lowermost layer, among the plurality of first organic insulating layers 131. The plurality of conductive bumps 135 may be disposed in a first region R1 of the second wiring portion 130. For example, at least a portion of the plurality of conductive bumps 135 may be disposed within a second insulating body 131 provided through the one or more first organic insulating layers 131 in the first region R1. The cavity C may expose at least a portion of each of the plurality of conductive bumps 135 from the one or more first organic insulating layers 131, for example, the plurality of first organic insulating layers 131. In this case, at least a portion of each of the plurality of semiconductor chips 151 and 152 may be disposed within the cavity C, and the plurality of semiconductor chips 151 and 152 may be connected to the one or more of the plurality of conductive bumps 135.

For example, in the printed circuit board 100A according to an example embodiment, a plurality of conductive bumps 135, each of which is connected to a first wiring layer 122 of the uppermost layer, among the one or more first wiring layers 122 of the first wiring portion 120, may be formed in the first region R1 of the second wiring portion 130, and the plurality of conductive bumps 135 may be exposed through the cavity C. In this case, a plurality of semiconductor chips 151 and 152, each of which is at least partially disposed within the cavity C, may be more easily mounted through the plurality of exposed conductive bumps 135, and may be more easily electrically connected to one or more first wiring layers 122 of the first wiring portion 120. Meanwhile, a surface treatment layer P may be formed on an exposed upper surface of each of the plurality of conductive bumps 135. Furthermore, the plurality of semiconductor chips 151 and 152 may be connected to the plurality of conductive bumps 135 through a plurality of first electrical connection metals 155. In this case, the connection reliability between the plurality of semiconductor chips 151 and 152 and the plurality of conductive bumps 135 may be further improved. If necessary, the plurality of conductive bumps 151 and 152 may be secured using underfill and/or a molding material, but the present disclosure is not limited thereto.

Referring to the drawings, the printed circuit board 100A according to an example embodiment may further include a solder resist layer 160 disposed on a lower side of the third wiring portion 140. The solder resist layer 160 may have a plurality of openings h respectively exposing at least a portion of a third wiring layer 142 of the lowermost layer, among the one or more third wiring layers 142. A plurality of second electrical connection metals 165 may be disposed on the plurality of openings h of the solder resist layer 160. The plurality of second electrical connection metals 165 may be connected to the lowermost third wiring layer 142.

For example, the printed circuit board 100A according to an example embodiment may have an electrical connection path for mounting on another substrate, such as a main board, on a lower side of the third wiring portion. For example, the printed circuit board 100A according to an example embodiment may be a Ball Grid Array (BGA) package board, but the present disclosure is not limited thereto.

Referring to the drawings, in the printed circuit board 100A according to an example embodiment, the one or more first organic insulating layers 131 may include a plurality of first organic insulating layers 131, and each of the plurality of first organic insulating layers 131 may include a photosensitive insulating material. For example, each of the first organic insulating layers 131 may include a photoimageable dielectric (PID). Meanwhile, the cavity C may penetrate through at least a portion of the first organic insulating layers 131, and inner surfaces of the first organic insulating layers 131 through which the cavity C penetrates, among the plurality of organic insulating layers 131 may have a step portion between the inner surfaces of the cavity C.

For example, the printed circuit board 100A according to an example embodiment, a second wiring portion 130 may be formed based on a plurality of photosensitive organic insulating layers, and the cavities C may be formed sequentially or stepwise on each photosensitive organic insulating layer. Accordingly, wall surfaces of partial cavities formed on each photosensitive organic insulating layer may have a step portion between layers. Furthermore, a cross-sectional width between the wall surfaces may gradually decrease toward a bottom surface of the cavity C. The cavity C having such a structure may be more easily formed on the photosensitive organic insulating layer, and also, the plurality of semiconductor chips 151 and 152 may be more easily mounted in the cavity C having such a structure.

Hereinafter, the components of the printed circuit board 100A will be described in more detail with reference to the drawings.

The glass layer 110 may include glass, which is an amorphous solid. The glass may include, for example, pure silicon dioxide (about 100% SiO₂), soda-lime glass, borosilicate glass, and aluminosilicate glass. However, the glass is not limited thereto, and alternative glass materials such as fluoroglass, phosphate glass, chalcogen glass, and the like, may also be used as the material. Additionally, other additives may be further included to form a glass having specific physical properties. The additives may include magnesium, calcium, manganese, aluminum, lead, boron, iron, chromium, potassium, sulfur, and/or antimony. Additionally, carbonates and/or oxides of these elements and other elements may be included. For example, the additives may include calcium carbonate (e.g., lime) and sodium carbonate (e.g., soda). The glass layer 110 may be a layer distinct from an organic insulating material including glass fiber (Glass Fiber, Glass Cloth or Glass Fabric), such as Copper Clad Laminate (CCL), Prepreg (PPG), and the like. For example, the glass layer 110 may include a large-area glass panel, such as a glass plate. The glass layer 110 may be used as a glass core.

The through-via 115 may include a metal. The metal may include copper (Cu), aluminum (Al), silver (Ag), tin (Sn), gold (Au), nickel (Ni), lead (Pb), titanium (Ti), and/or alloys thereof. The through-via 115 may perform various functions depending on the design. For example, the through-via 115 may include a ground via, a power via and a signal via. The through-via 115 may have a substantially circular or oval shape in plan view, and a substantially columnar or hourglass shape in cross-section, but the present disclosure is not limited thereto. The through-via 115 may be formed within a through-hole penetrating between the upper surface and the lower surface of the glass layer 110. For example, the through-via 115 may be a Through-Glass Via (TGV). The through-via 115 may include a sputtered layer (e.g., sputtered titanium/copper) as a seed layer and an electrolytically plated layer (e.g., electrolytic copper) as a fill-plated layer. However, the present disclosure is not limited thereto, and the through-via may include an electroless plated layer (e.g., chemical copper) as the seed layer, or may include both the sputtered layer and the electroless plated layer. If necessary, the fill-plated layer of the through-via 115 may be formed conformally, and a filler may be filled between the fill-plated layers. The upper surface and the lower surface of the through-via 115 may be substantially coplanar with the upper surface and the lower surface of the glass layer 110, respectively, but the present disclosure is not limited thereto. For example, the upper surface and the lower surface of the through-via 115 may be recessed more inwardly than the upper and lower surfaces of the glass layer 110, respectively. For example, the upper surface of the through-via 115 may be disposed lower than the upper surface of the glass layer 110, and the lower surface of the through-via 115 may be disposed higher than the lower surface of the glass layer 110. For example, a recessed step portion may be formed between the upper surface and the lower surface of the glass layer 110 and the upper surface and the lower surface of the through-via 115, respectively. The through-via 115 may be provided in plural, and the above-described features may be independently applied to each through-via 115.

Each of the one or more inorganic insulating layers 121 may include an inorganic insulating material. The inorganic insulating material may be, for example, silicon oxide or silicon nitride. For example, each of the one or more inorganic insulating layers 121 may include one or more of a silicon oxide film and a silicon nitride film. However, the present disclosure is not limited thereto, and other inorganic insulating materials used as inorganic insulating film materials in a semiconductor process may also be used. For example, each of the one or more inorganic insulating layers 121 may include silicon dioxide (SiO₂), silicon nitride (SiN), aluminum oxide (Al₂O₃), hafnium oxide (HfO₂), zirconium oxide (ZrO₂), titanium oxide (TiO₂), boron nitride (BN), and/or silicon carbide (SiC), but the present disclosure is not limited thereto. In one example, the one or more inorganic insulating layers 121 may be a single layer, but is not limited thereto. The one or more inorganic insulating layers 121 may provide a first insulating body 121 to the first wiring portion 120. For example, the one or more inorganic insulating layers 121 may collectively provide a single first insulating body 121.

Each of the one or more first wiring layers 122 may include a metal. The metal may include copper (Cu), aluminum (Al), silver (Ag), tin (Sn), gold (Au), nickel (Ni), lead (Pb), titanium (Ti), and/or alloys thereof. Each of the one or more first wiring layers 122 may perform various functions depending on the design. For example, the one or more first wiring layers 122 may include a signal pattern, a power pattern, and a ground pattern. These patterns may each have various shapes, such as lines, planes, and pads. The one or more first wiring layers 122 may primarily include signal patterns, but the present disclosure is not limited thereto. Each of the one or more first wiring layers 122 may include a sputtered layer (e.g., sputtered titanium/copper) as a seed layer and an electrolytically plated layer (e.g., electrolytic copper) as a pattern layer. However, the present disclosure is not limited thereto, and the one or more first wiring layers 122 may include an electroless plated layer (e.g., chemical copper) as the seed layer, or may include both a sputtered layer and an electroless plated layer. One or more first wiring layers 122 may provide a relatively high-density wiring line to the first insulating body 121.

Each of the one or more first wiring vias 123 may include a metal. The metal may include copper (Cu), aluminum (Al), silver (Ag), tin (Sn), gold (Au), nickel (Ni), lead (Pb), titanium (Ti), and/or alloys thereof. Each of the one or more first wiring vias 123 may include a filled via filling a via hole, but may also include a conformal via disposed along a wall surface of the via hole. Each of the one or more first wiring vias 123 may perform various functions depending on the design thereof. For example, the one or more first wiring vias may include a ground via, a power via, a signal via, and the like. The one or more first wiring vias 123 may primarily include signal vias. Each of the one or more first wiring vias 123 may include a sputtered layer (e.g., sputtered titanium/copper) as a seed layer, and an electrolytically plated layer (e.g., electrolytic copper) as a pattern layer. However, the present disclosure is not limited thereto, and the one or more first wiring vias 123 may include an electroless plating layer (e.g., chemical copper) as the seed layer may, or may include both a sputtered layer and an electroless plating layer. The one or more first wiring vias 123 may have a substantially tapered shape in which a width of an upper end is wider than a width of a lower end, in cross-section. The one or more first wiring vias 123 may provide an electrical connection path to the first insulating body 121. For example, when the one or more first wiring layers 122 are comprised of a plurality of layers, the one or more first wiring vias 123 may be a plurality of first wiring vias 123, and the plurality of first wiring vias 123 may electrically connect the plurality of first wiring layers 122 to each other. If necessary, when one or more first wiring layers 122 are not formed on an upper surface of the glass layer 110, the one or more first wiring layers 122 and the through-vias 115 may be electrically connected to each other.

Each of the one or more first organic insulating layers 131 may include an organic insulating material. The organic insulating material may include a thermosetting resin such as an epoxy resin, a thermoplastic resin such as a polyimide, or a material including an inorganic filler and/or an organic filler along with the resin. For example, each of the one or more first organic insulating layers 131 may include a non-photosensitive insulating material such as Ajinomoto Build-up Film (ABF) or a photosensitive insulating material such as Photoimageable Dielectric (PID), but the present disclosure is not limited thereto. In one example, each of the one or more first organic insulating layers 131 may include a photosensitive insulating material such as Photoimageable Dielectric (PID), but the present disclosure is not limited thereto. When the one or more first organic insulating layers 131 are comprised of a plurality of layers, boundaries thereof may be distinct from each other, but the first organic insulating layers 131 may also be integrated without distinct boundaries. When the interlayer boundaries of the first organic insulating layers 131 are unclear, the layers of the first organic insulating layers 131 may be distinguished by the second wiring layers 132 formed on different layers. The one or more first organic insulating layers 131 may provide the second insulating body 131 to the second wiring portion 130. For example, the one or more first organic insulating layers 131 may collectively form a single second insulating body 131.

The cavity C may penetrate through at least a portion of one or more first organic insulating layers 131, for example, at least a portion of the first insulating body 131. For example, when the one or more first organic insulating layers 131 are a plurality of first organic insulating layers 131, the cavity C may penetrate through each of the remaining first organic insulating layers 131 except for a first organic insulating layer 131 of the lowermost layer, among the plurality of organic insulating layer 131, and the first organic insulating layer 131 of the lowermost layer may provide a bottom surface of the cavity C. The plurality of first organic insulating layers 131 may include a photosensitive organic insulating material, and in this case, inner surfaces providing a wall surface of the cavity C of the remaining first organic insulating layers 131 except for the first organic insulating layer 131 of the lowermost layer may have a step portion between layers, but the present disclosure is not limited thereto. When viewed from the top, the cavity C may have a roughly rectangular shape based on an outermost edge thereof, and in this case, each of four corners thereof is a roughly curved surface, but the present disclosure is not limited thereto.

Each of the one or more second wiring layers 132 may include a metal. The metal may include copper (Cu), aluminum (Al), silver (Ag), tin (Sn), gold (Au), nickel (Ni), lead (Pb), titanium (Ti), and/or alloys thereof. Each of the one or more second wiring layers 132 may perform various functions depending on the design. For example, the second wiring layers 132 may include a signal pattern, a power pattern, and a ground pattern. Alternatively, the second wiring layers 132 may include a capacitor pattern, an inductor pattern, and a dummy pattern. Each of these patterns may have various shapes, such as a line, a plane, or a pad. Each of the one or more second wiring layers 132 may primarily include patterns other than signal patterns, but the present disclosure is not limited thereof. Each of the one or more second wiring layers 132 may include an electroless plating layer (e.g., chemical copper) as a seed layer and an electrolytic plating layer (e.g., electrolytic copper) as a pattern layer. However, the present disclosure is not limited thereto, and the second wiring layers 132 may include a sputtered layer (e.g., sputtered titanium/copper) as the seed layer, or may include both a sputtered layer and an electroless plating layer. Each of the one or more second wiring layers 132 may provide a relatively low-density wiring line to the second insulating body 131. Furthermore, the second wiring layers 132 may provide a conductive pattern with various functions.

Each of the one or more second wiring vias 133 may include a metal. The metal may include copper (Cu), aluminum (Al), silver (Ag), tin (Sn), gold (Au), nickel (Ni), lead (Pb), titanium (Ti), and/or alloys thereof. Each of the one or more second wiring vias 133 may include a filled via filling the via hole, but may also include a conformal via disposed along a wall surface of the via hole. Each of the one or more second wiring vias 133 may perform various functions depending on the design. For example, the second wiring vias 133 may include a ground via, a power via, and a signal via. Alternatively, the second wiring vias 133 may include a capacitor via, an inductor via, and a dummy via. The one or more second wiring vias 133 may primarily include vias other than signal vias, but the present disclosure is not limited thereto. Each of the one or more second wiring vias 133 may include an electroless plating layer (e.g., chemical copper) as the seed layer, and an electrolytic plating layer (e.g., electrolytic copper) as the pattern layer. However, the present disclosure is not limited thereto, and the second wiring vias 133 may include a sputtered layer (e.g., sputtered titanium/copper) as the seed layer, or may include both a sputtered layer and an electroless plating layer. The one or more second wiring vias 133 may have a substantially tapered shape in which the width of the upper end is wider than the width of the lower end, in a cross-section. For example, the one or more first and second wiring vias 123 and 133 may be tapered in substantially the same direction. The one or more second wiring vias 133 may provide an electrical connection path to the second insulating body 131. For example, when the one or more second wiring layers 132 are comprised of a plurality of layers, the one or more second wiring vias 133 may be a plurality of second wiring vias 133. In this case, some of the second wiring vias 133 may electrically connect the first and second wiring layers 122 and 132 to each other, and others thereof may electrically connect the second wiring layers 132 to each other.

Each of the plurality of conductive bumps 135 may include a metal. The metal may include copper (Cu), aluminum (Al), silver (Ag), tin (Sn), gold (Au), nickel (Ni), lead (Pb), titanium (Ti), and/or alloys thereof. Each of the plurality of conductive bumps 135 may be a metal post, for example, a copper post, but the present disclosure is not limited thereto. Each of the plurality of conductive bumps 135 may include a signal bump, a power bump, and a ground bump, and may mostly include signal bumps, but the present disclosure is not limited thereto. Each of the plurality of conductive bumps 135 may include an electroless plating layer (e.g., chemical copper) as the seed layer and an electrolytic plating layer (e.g., electrolytic copper) as the pattern layer. However, the present disclosure is not limited thereto, and the conductive bumps 135 may include a sputtered layer (e.g., sputtered titanium/copper), or both a sputtered layer and an electroless plating layer. Each of the plurality of conductive bumps 135 may be buried in the first organic insulating layer 131 of the lowermost layer, and respective upper surfaces or upper portions thereof may be exposed through the cavity C. An upper surface of each of the plurality of conductive bumps 135 may be substantially coplanar with an upper surface of the first organic insulating layer 131 of the lowermost layer. However, the present disclosure is not limited thereto, and a portion of each of the plurality of conductive bumps 135 may protrude onto the upper surface of the first organic insulating layer 131 of the lowermost layer.

The surface treatment layer P may be disposed on an exposed upper surface or a portion thereof of each of the plurality of conductive bumps 135. The surface treatment layer P may be formed of a single metal, such as copper (Cu), nickel (Ni), palladium (Pd), gold (Au), or tin (Sn), or combinations thereof. These metals may be formed through methods such as plating, sputtering, deposition, or reflow. The surface treatment layer P may contribute to improved reliability throughout a packaging process by controlling the formation of intermetallic compounds, minimizing electrical contact resistance, preventing oxidation, and enhancing wettability during the reflow process. For example, when each of the plurality of conductive bumps 135 includes a copper post, the surface treatment layer P may have a multilayer structure comprising a nickel layer, a copper layer, and a tin layer. For example, each metal post 135 having the surface treatment layer P formed thereon may have a CNCS (Cu/Ni/Cu/Sn) bump structure, but is not limited thereto, and may have other combinations of bump structures, such as a CS (Cu/Sn) bump structure.

Each of the one or more second organic insulating layers 141 may include an organic insulating material. The organic insulating material may include a thermosetting resin such as an epoxy resin, a thermoplastic resin such as a polyimide, or a material comprising a resin and inorganic and/or organic fillers. For example, each of the one or more second organic insulating layers 141 may include a non-photosensitive insulating material such as Ajinomoto Build-up Film (ABF) or a photosensitive insulating material such as Photoimageable Dielectric (PID), but the present disclosure is not limited thereto. In one example, each of the one or more second organic insulating layers 141 may include a photosensitive insulating material such as a Photoimageable Dielectric (PID), but the present disclosure is not limited thereto. When the one or more second organic insulating layers 141 are comprised of a plurality of layers, boundaries thereof may be distinct from each other, but the second organic insulating layers 141 may also be integrated without distinct boundaries. When the interlayer boundaries of the second organic insulating layers 141 are unclear, the layers of the second organic insulating layers 141 may be distinguished by third wiring layers 142 formed on different layers. The one or more second organic insulating layers 141 may provide a third insulating body 141 to the third wiring portion 140. For example, the one or more second organic insulating layers 141 may collectively provide a single third insulating body 141.

Each of the one or more third wiring layers 142 may include a metal. The metal may include copper (Cu), aluminum (Al), silver (Ag), tin (Sn), gold (Au), nickel (Ni), lead (Pb), titanium (Ti), and/or alloys thereof. Each of the one or more third wiring layers 142 may perform various functions depending on the design. For example, the third wiring layers 142 may include a signal pattern, a power pattern, and a ground pattern. The one or more third wiring layers 142 may primarily include power patterns, but the present disclosure is not limited thereto. These patterns may each have various shapes, such as lines, planes, and pads. Each of the one or more third wiring layers 142 may include an electroless plating layer (e.g., chemical copper) as the seed layer and an electrolytic plating layer (e.g., electrolytic copper) as the pattern layer. However, the present disclosure is not limited thereto, and the third wiring layers 142 may include a sputtered layer (e.g., sputtered titanium/copper) as the seed layer, or both a sputtered layer and an electroless plating layer. The one or more third wiring layers 142 may provide a relatively low-density wiring line to the third insulating body 141.

Each of the one or more third wiring vias 143 may include a metal. The metal may include copper (Cu), aluminum (Al), silver (Ag), tin (Sn), gold (Au), nickel (Ni), lead (Pb), titanium (Ti), and/or alloys thereof. Each of the one or more third wiring vias 143 may include a filled via filling a via hole, but may also include a conformal via disposed along a wall surface of the via hole. Each of the one or more third wiring vias 143 may perform various functions depending on the design. For example, it may include a ground via, a power via and a signal via. The one or more third wiring vias 143 may primarily include power vias, but the present disclosure is not limited thereto. Each of the one or more third wiring vias 143 may include an electroless plating layer (e.g., chemical copper) as the seed layer and an electrolytic plating layer (e.g., electrolytic copper) as the pattern layer. However, the present disclosure is not limited thereto, and the third wiring via 143 may include a sputtered layer (e.g., sputtered titanium/copper) as the seed layer, or may include both a sputtered layer and an electroless plating layer. The one or more third wiring vias 143 may have a substantially tapered shape in which the width of the lower portion is wider than the width of the upper portion, in cross-section. For example, the one or more third wiring vias 143 may be tapered in a direction substantially opposite to that of the one or more first and second wiring vias 123 and 133. The one or more third wiring vias 143 may provide an electrical connection path to the third insulating body 141. For example, when the one or more third wiring layers 142 are comprised of a plurality of layers, the one or more third wiring vias 143 may be a plurality of third wiring vias 143. Some of the third wiring vias 143 may electrically connect the through-vias 115 and the third wiring layers 142, while others thereof may electrically connect the third wiring layers 142 to each other.

Each of the plurality of semiconductor chips 151 and 152 may each include an integrated circuit (IC) die with hundreds to millions of devices integrated into a single chip. The IC may be, for example, a logic chip such as a central processor (CPU), a graphics processor (GPU), a field programmable gate array (FPGA), a digital signal processor (DSP), an encryption processor, a microprocessor, a microcontroller, an application processor (AP), an analog-to-digital converter, or an application-specific IC (ASIC). However, the present disclosure is not limited thereto, and the IC may be a memory chip, such as a volatile memory (e.g., DRAM), a non-volatile memory (e.g., ROM), a flash memory, or an HBM (High Bandwidth Memory), and may also be a system-on-chip (SoC) that integrates various functions into a single chip. For example, the first semiconductor chip 151 may be a logic chip, such as a CPU or GPU, and the second semiconductor chip 152 may be a memory chip, such as HBM, and in this case, a plurality of second semiconductor chips 152 may be disposed around the first semiconductor chip 151. Alternatively, the first semiconductor chip 151 may be an input/output die, and the second semiconductor chip 152 may be a chiplet of a logic chip, such as a CPU or GPU, and/or a memory chip, such as HBM, and in this case, a plurality of second semiconductor chips 152 may be disposed around the first semiconductor chip 151. For example, a highly integrated package configuration may be possible.

Each of the plurality of first electrical connection metals 155 may include a metal. The metal may include copper (Cu), aluminum (Al), silver (Ag), tin (Sn), gold (Au), nickel (Ni), lead (Pb), titanium (Ti), and/or alloys thereof. For example, each of the plurality of first electrical connection metals 155 may include a copper bump. Alternatively, each of the plurality of first electrical connection metals 155 may include a solder bump. Alternatively, each of the plurality of first electrical connection metals 155 may include a combination of copper bumps and solder bumps. The plurality of first electrical connection metals 155 may be used for mounting the plurality of semiconductor chips 151 and 152. For example, each of the plurality of first electrical connection metals 155 may be bonded to each of the plurality of conductive bumps 135, more specifically, to a surface treatment layer P formed on each of the plurality of conductive bumps 135.

The solder resist layer 160 may include a liquid or film-type solder resist. However, the present disclosure is not limited thereto, and other types of insulating materials, such as ABF, may also be used. A surface treatment layer and/or a metal bump may be formed on each pattern exposed through the plurality of openings h, as needed. Each pattern exposed through the plurality of openings h may be in the form of a Solder Mask Defined (SMD) and/or Non-Solder Mask Defined (NSMD), but the present disclosure is not limited thereto. The solder resist layer 160 may protect internal components of the printed circuit board 100A, such as the third wiring portion 140.

Each of the plurality of second electrical connection metals 165 may be formed of a low-melting-point metal, such as solder such as tin (Sn), aluminum (Al), or copper (Cu). However, this is merely an example, and the material is not particularly limited thereto. Each of the plurality of second electrical connection metals 165 may be a ball, a pin, or the like. The plurality of second electrical connection metals 165 may be formed as either multiple layers or a single layer. When formed as multiple layers, the second electrical connection metals 165 may include a copper pillar and a solder. When formed as a single layer, the second electrical connection metals 165 may include tin-silver solder, but the present disclosure is not limited thereto. The plurality of second electrical connection metals 165 may be used to mount the printed circuit board 100A on another substrate, such as a main board.

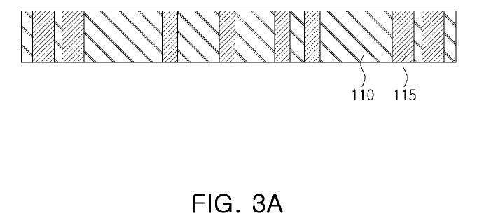

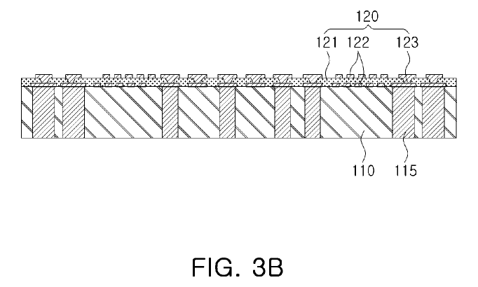

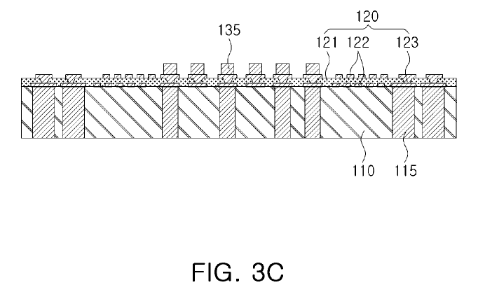

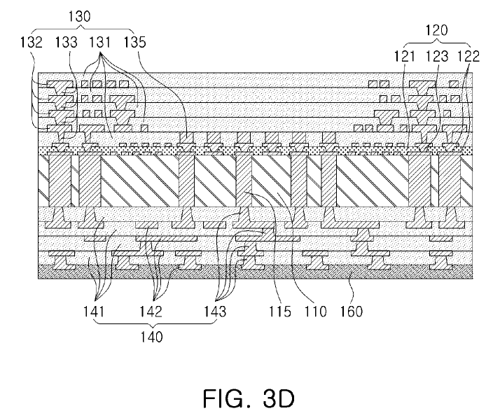

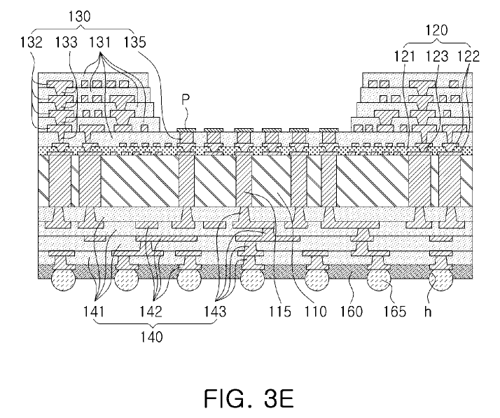

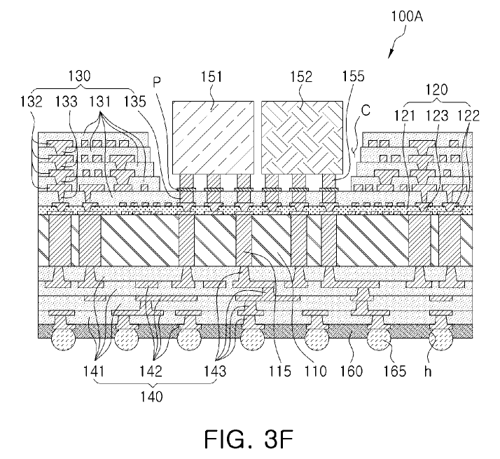

FIGS. 3A to 3F are cross-sectional views schematically illustrating an example of a printed circuit board manufacturing process.

Referring to FIG. 3A, a glass layer 110 may be prepared. The glass layer 110 may be in the form of a glass plate. Therefore, the glass layer 110 may be easily applied to large-area substrates. The glass layer 110 may have a substantially rectangular shape in cross-section, and may have a substantially square or rectangular shape in plan view, but the present disclosure is not limited thereto. Next, a through-via 115 may be formed in the glass layer 110. For example, a through-hole may be formed in the glass layer 110 using various methods, such as laser processing, mechanical processing, or chemical processing, a seed layer may be formed on a wall surface of the through-hole, and a fill-plated layer may be formed to fill at least a portion of the through-hole, thus forming the through-via 115. The through-hole may be formed to penetrate between the upper and lower surfaces of the glass layer 110. The seed layer may be formed by sputtering a material containing titanium and a material containing copper, and the fill-plated layer may be formed by electrolytic plating a material containing copper, but the present disclosure is not limited thereto. The seed layer and plating layer on the upper and lower surfaces of the glass layer 110 may be removed by etching and/or polishing. A plurality of through-vias 115 may be formed in the glass layer 110.

Referring to FIG. 3B, a first wiring layer 122 may be formed on the upper surface of the glass layer 110. The first wiring layer 122 may include a line pattern having a fine pitch, and a pad pattern covering an upper surface of the through-via 115. These patterns may be formed using a dry film photolithography process and a plating process. The plating process may be performed by sputtering a material including titanium and a material containing copper to form a seed layer, and electroplating a material containing copper to form a pattern layer, but the present disclosure is not limited thereto. Next, an inorganic insulating layer 121 may be formed on the upper surface of the glass layer 110. The inorganic insulating layer 121 may cover the first wiring layer 122 that is formed previously. The inorganic insulating layer 121 may be formed using chemical vapor deposition (CVD), physical vapor deposition (PVD), or atomic layer deposition (ALD), but the present disclosure is not limited thereto. The inorganic insulating layer 121 may be formed in the form of a thin film. Next, a first wiring via 123 penetrating through the inorganic insulating layer 121 may be formed. Furthermore, a first wiring layer 122 may be further formed on an upper surface of the inorganic insulating layer 121. The first wiring via 123 may include a via pattern having a fine pitch. The additionally formed first wiring layer 122 may include a line pattern having a fine pitch, and a pad pattern covering the upper surface of the via pattern. The first wiring via 123 may be formed by forming a via hole in the inorganic insulating layer 121 through an etching process, and then performing the plating process described above on the via hole. The additionally formed first wiring layer 122 may be formed using the photolithography and plating processes described above. Through this series of processes, the first wiring portion 120 may be formed.

Referring to FIG. 3C, a plurality of conductive bumps 135 may be formed on the additionally formed first wiring layer 122. For example, a plurality of conductive bumps 135 may be respectively formed on a plurality of pad patterns disposed in a control region on a planar surface, among the plurality of pad patterns of the first wiring layer 122 formed on the upper surface of the inorganic insulating layer 121. The plurality of conductive bumps 135 may be formed using a dry film photolithography process and a plating process. The plating process may involve forming a seed layer by performing electroless plating with a material including copper, and forming a patterned layer on the seed layer by performing electrolytic plating with the material including copper, but the present disclosure is not limited thereto. If necessary, all or part of the surface treatment layer P, described below, may be formed on each of the plurality of conductive bumps 135. The surface treatment layer P may be formed using methods such as plating, sputtering, deposition, or reflow, depending on the material used.

Referring to FIG. 3D, one or more first organic insulating layers 131, one or more second wiring layers 132, and one or more second wiring vias 133 may be formed on an upper surface of the inorganic insulating layer 121. Furthermore, one or more second organic insulating layers 141, one or more third wiring layers 142, and one or more third wiring vias 143 may be formed on the lower surface of the glass layer 110. Each of these layers may be formed into a plurality of layers. For example, a build-up process may be performed on both sides of the glass layer 110 and the first wiring portion 120. The build-up process may include stacking an organic insulating layer, forming a via hole in the organic insulating layer, and forming a wiring via and a wiring layer on the via hole and the organic insulating layer, respectively. The stacking of the organic insulating layer may be, for example, stacking a photosensitive insulating material. The via hole may be formed, for example, through a photolithography process and an etching process. The wiring via may be formed through a plating process including electroless plating and electrolytic plating. The wiring layer may also be formed through a plating process including electroless plating and electrolytic plating. The build-up process may be repeated on both sides of the glass layer 110 and the first wiring portion 120. For example, the build-up process may be repeated until a desired number of layers are reached. Through a series of processes, a second wiring portion 130 and a third wiring portion 140 may be formed. Meanwhile, for the second wiring portion 130, the second wiring layer 132 and the second wiring via 133 may not be formed in a central region corresponding to a region in which the plurality of conductive bumps 135 are formed on the plane, and the second wiring layer 132 and the second wiring via 133 may be formed only in a peripheral region surrounding the central region. Meanwhile, for the second wiring portion 130, if necessary, a stopper layer including titanium (Ti) or the like may be formed on a plurality of conductive bumps 150 during the build-up process. For example, the stopper layer may be formed on the plurality of conductive bumps 150 in a central region on the planar plane described above, through a sputtering or plating process. The stopper layer may be a layer for forming a cavity C, as described below. Next, a solder resist layer 160 may be formed on a lower side of the third wiring portion 140. The solder resist layer 160 may be formed by stacking or coating a solder resist material.

Referring to FIG. 3E, a cavity C may be formed in the central region on the above-described plane of the second wiring portion 130. The cavity C may be formed in a method of performing a photo process and an etching process on each first organic insulating layer 131 to form each sub-cavity in stages. The cavity C may be formed up to the stuffer layer described above. After the cavity C is formed, the stuffer layer may be removed by etching or the like. Meanwhile, the stuffer layer described above may not be formed, in which case a stuffer layer removal process may be unnecessary. When the cavity C is formed, at least a portion of each of the plurality of conductive bumps 135 may be exposed through the cavity C. A surface treatment layer P may be formed on at least a portion of each of the exposed portions of the plurality of conductive bumps 135. Meanwhile, as described above, when a portion or all of the surface treatment layer P is pre-formed on each of the plurality of conductive bumps 135, a portion or all of each surface treatment layer P may be exposed through the cavity C. When only a portion of each surface treatment layer P is pre-formed, the remaining portion of each surface treatment layer P may be formed after forming the cavity C. The surface treatment layer P may be formed through methods such as plating, sputtering, deposition, or reflow, depending on the material used. Next, a plurality of openings h may be formed in the solder resist layer 160 using a photo process, an etching process, or laser processing. Furthermore, solder balls or the like may be attached to each of the plurality of openings h, thereby forming a plurality of second electrical connection metals 165.

Referring to FIG. 3F, a plurality of semiconductor chips 151 and 152 may be mounted in the cavity C. The plurality of semiconductor chips 151 and 152 may be connected to a surface treatment layer P formed on the plurality of conductive bumps 135 using a plurality of first electrical connection metals 155. After mounting the plurality of semiconductor chips 151 and 152, further underfilling and/or molding may be performed. Although the printed circuit board 100A according to the above-described example may be manufactured through a series of processes, a manufacturing process is not necessarily limited thereto. Other details may be substantially the same as those described for the printed circuit board 100A according to the above-described example.

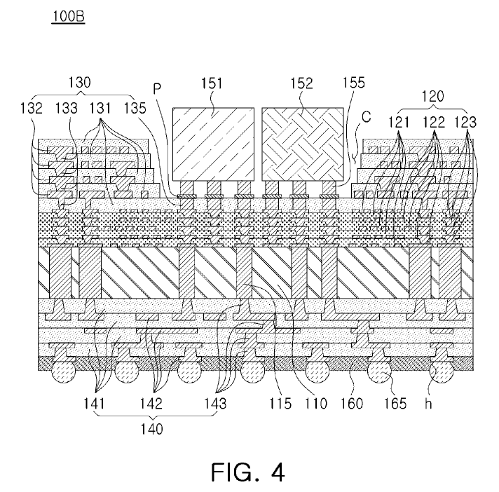

FIG. 4 is a cross-sectional view schematically illustrating a modified example of a printed circuit board.

Referring to the drawing, a printed circuit board 100B according to a modified example embodiment may configured so that a first wiring portion 120 may be formed in more multiple layers, in contrast to the printed circuit board 100A according to the above-described example embodiment. For example, the first wiring portion 120 may include a plurality of inorganic insulating layers 121, a plurality of first wiring layers 122 respectively disposed on or within the plurality of inorganic insulating layers 121, and a plurality of first wiring vias 123 respectively disposed within the plurality of inorganic insulating layers 121. For example, a high-density wiring line may be formed in more multiple layers, in which case more complex and diverse wiring designs may be performed. The plurality of inorganic insulating layers 121 may include the inorganic insulating material described above, and each layer may include substantially the same inorganic insulating material. In this case, the plurality of inorganic insulating layers 121 may have distinct boundaries, but may also be integrated without distinct boundaries. When the interlayer boundaries of the plurality of inorganic insulating layers 121 are unclear, the layers of the plurality of inorganic insulating layers 121 may be distinguished by the plurality of first wiring layers 122 formed on different layers. The plurality of inorganic insulating layers 121 may collectively provide a single second insulating body 131. Other details may be substantially the same as those described for the printed circuit board 100A according to the above-described example embodiment.

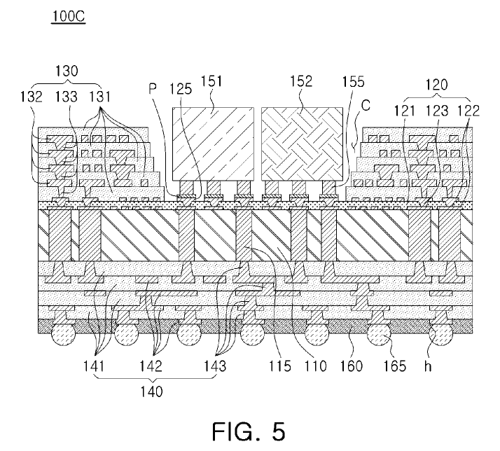

FIG. 5 is a cross-sectional view schematically illustrating another modified example embodiment of a printed circuit board.

Referring to the drawing, a printed circuit board 100C according to another modified example embodiment may may be configured so that one or more first wiring layers 122, for example, the first wiring layer 122 of the uppermost layer, among the plurality of first wiring layers 122, may include a plurality of conductive pads 125, in the printed circuit board 100A according to the above-described example embodiment. Additionally, the cavity C may expose at least a portion of each of the plurality of conductive pads 125, from one or more first organic insulating layers 131, for example, the plurality of first organic insulating layers 131, such as the second insulating body 131. For example, the plurality of conductive bumps 135 described in the above-described example may be omitted, and the cavity C may be formed to be deeper. For example, as in the above-described example embodiment, the cavity C may not penetrate through a portion from an upper surface to a lower surface of the second insulating body 131, but may penetrate from the upper surface to the lower surface of the second insulating body 131. The plurality of conductive pads 125 may be disposed in the above-described first region R1. A surface treatment layer P may be disposed on at least a portion of each of the plurality of conductive pads 125. Each of the plurality of semiconductor chips 151 and 152 may be connected to one or more of the plurality of conductive pads 125. This simplifies the process. Furthermore, since the cavity C may be formed to be deeper, a thickness of the product after mounting the plurality of semiconductor chips 151 and 152 may be made thinner. Other details may be substantially the same as those described for the printed circuit board 100A according to the above-described example embodiment.

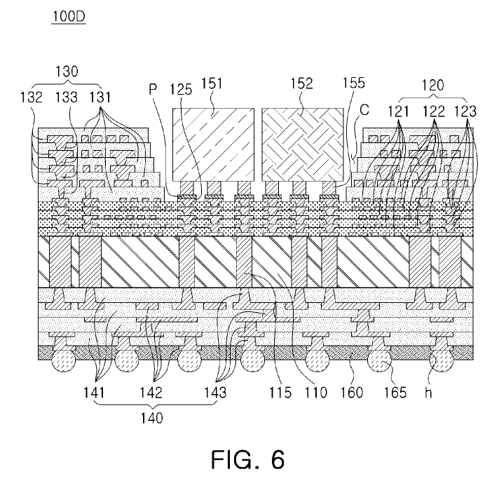

FIG. 6 is a cross-sectional view schematically illustrating another modified example embodiment of a printed circuit board.

Referring to the drawing, a printed circuit board 100D according to another modified example embodiment may be configured so that a first wiring portion 120 may include a plurality of inorganic insulating layers 121, a plurality of first wiring layers 122 respectively disposed on or within the plurality of inorganic insulating layers 121, and a plurality of first wiring vias 123 respectively disposed within the plurality of inorganic insulating layers 121, in the printed circuit board 100A according to the above-described example embodiment. Furthermore, a first wiring layer 122 of the uppermost layer, among the plurality of first wiring layers 122, may include a plurality of conductive pads 125, a cavity C may expose at least a portion of each of the plurality of conductive pads 125, and a surface treatment layer P may be disposed on at least a portion of each of the exposed portions of each of the plurality of conductive pads 125. Additionally, each of the plurality of semiconductor chips 151 and 152 may be connected to one or more of the plurality of conductive pads 125. For example, the printed circuit board 100D according to another modified example embodiment may be a combination of the printed circuit board 100A according to an example embodiment, the printed circuit board 100B according to another modified example embodiment, and the printed circuit board 100C according to another modified example embodiment. Other details may be substantially the same as those described for the printed circuit board 100A according to an example embodiment, the printed circuit board 100B according to another modified example embodiment, and the printed circuit board 100C according to another modified example embodiment.

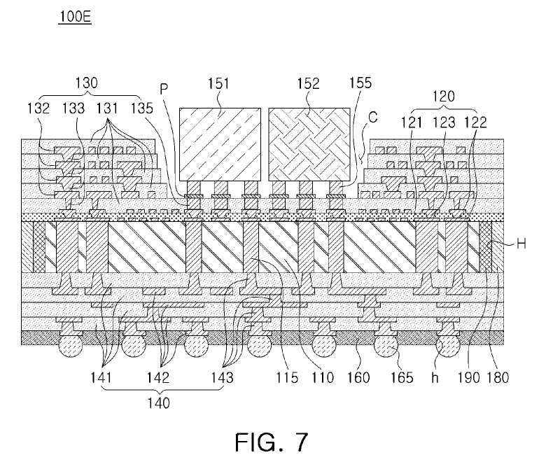

FIG. 7 is a cross-sectional view schematically illustrating another modified example embodiment of a printed circuit board.

Referring to the drawing, a printed circuit board 100E according to another modified example embodiment, may further include a frame 180 having a through-portion H and an insulating material 190 filling at least a portion of the through-portion H, in the printed circuit board 100A according to the above-described example. At least a portion of the glass layer 110 may be disposed within the through-portion H, and the insulating material 190 may be disposed between the frame 180 and the glass layer 110. One or more inorganic insulating layers 121, such as a first insulating body 121, may cover an upper surface of the glass layer 110, an upper surface of the frame 180, and an upper surface of the insulating material 190, respectively. One or more second organic insulating layers 141, such as the third insulating body 141, may cover the lower surface of the glass layer 110, the lower surface of the frame 180, and the lower surface of the insulating material 190, respectively. The insulating material 190 may be formed through a separate filling process, and thus may have an interlayer boundary with the second organic insulating layer 141 of the uppermost layer. However, the present disclosure is not limited thereto, and the insulating material 190 may also be formed from the second organic insulating layer 141 of the uppermost layer, in which case the layers may be integrated without an interlayer boundary. The frame 180 may be used as a jig during the process, and thus may be advantageous for process warpage control, or the like. Additionally, a large-area frame 180 may be formed with a plurality of through-portion H, which may be used to manufacture a plurality of printed circuit boards 100E through the same process and then, the plurality of printed circuit boards 100E are separately manufactured through a cutting process, thereby increasing productivity. The frame 180 may include various materials. For example, the frame 180 may include an organic insulating material such as Copper Clad Laminate (CCL). Alternatively, the frame 180 may include an inorganic insulating material such as silicon or ceramic. Alternatively, the frame 180 may include a metal such as copper (Cu). However, the present disclosure is not limited thereto. The through-portions H may penetrate between an upper surface and a lower surface of the frame 180. The insulating material 190 may include an organic insulating material substantially identical to the uppermost second organic insulating layer 141, but the present disclosure is not limited thereto, and the insulating material 190 may include different organic insulating materials. For example, various organic insulating materials that are easy to fill may be used as the insulating material 190. Other details may be substantially the same as those described for the printed circuit board 100A according to the above-described example.

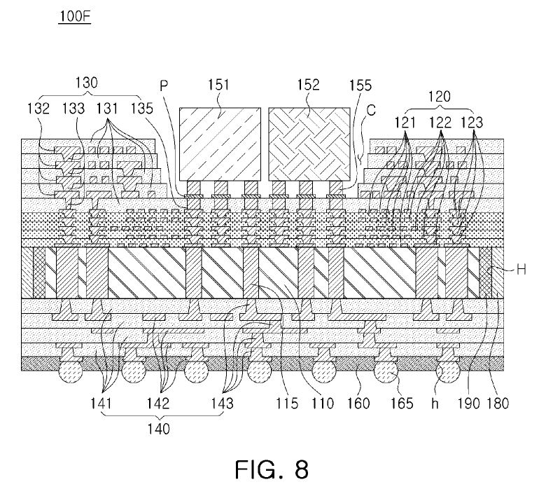

FIG. 8 is a cross-sectional view schematically illustrating another modified example embodiment of a printed circuit board.

Referring to the drawing, a printed circuit board 100F according to another modified example embodiment may further include a frame 180 having a through-portion H and an insulating material 190 filling at least a portion of the through-portion H, in the printed circuit board 100A according to the above-described example embodiment. Furthermore, a first wiring portion 120 may include a plurality of inorganic insulating layers 121, a plurality of first wiring layers 122 respectively disposed on or within the plurality of inorganic insulating layers 121, and a plurality of first wiring vias 123 respectively disposed within the plurality of inorganic insulating layers 121. For example, the printed circuit board 100F according to another modified example embodiment may be a combination of the printed circuit board 100A according to an example embodiment, the printed circuit board 100B according to another modified example embodiment, and the printed circuit board 100E according to another modified example embodiment. Other details may be substantially the same as those described for the printed circuit board 100A according to an example embodiment, the printed circuit board 100B according to another modified example embodiment, and the printed circuit board 100E according to another modified example embodiment.

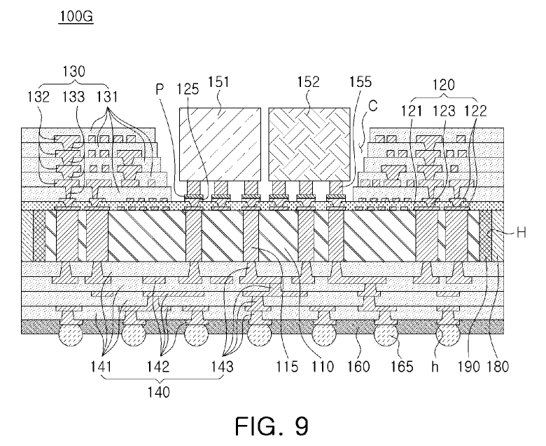

FIG. 9 is a cross-sectional view schematically illustrating another modified example embodiment of a printed circuit board.

Referring to the drawing, a printed circuit board 100G according to another modified example embodiment may further include a frame 180 having a through-portion H and an insulating material 190 filling at least a portion of the through-portion H, in the printed circuit board 100A according to the above-described example embodiment. Furthermore, one or more first wiring layers 122, for example, the first wiring layer 122 of the uppermost layer, among the plurality of first wiring layers 122, may include a plurality of conductive pads 125. A cavity C may expose at least a portion of each of the plurality of conductive pads 125, and a surface treatment layer P may be disposed on at least a portion of each of the exposed conductive pads 125. Furthermore, each of the plurality of semiconductor chips 151 and 152 may be connected to at least one of the plurality of conductive pads 125. For example, the printed circuit board 100G according to another modified example embodiment may be a combination of the printed circuit board 100A according to an example embodiment, the printed circuit board 100C according to another modified example embodiment, and the printed circuit board 100E according to another modified example embodiment. Other details may be substantially the same as those described for the printed circuit board 100A according to an example embodiment, the printed circuit board 100C according to another modified example embodiment, and the printed circuit board 100E according to another modified example embodiment.

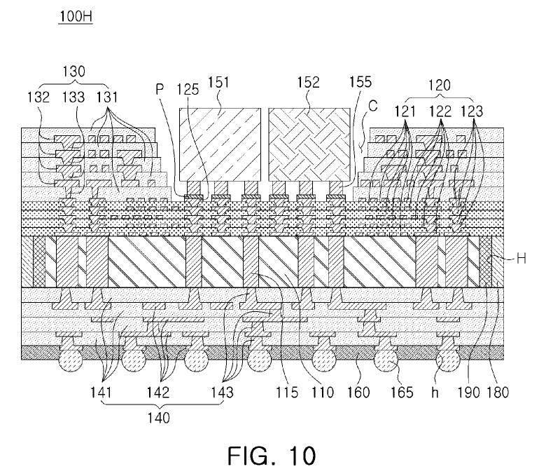

FIG. 10 is a cross-sectional view schematically illustrating another modified example embodiment of a printed circuit board.

Referring to the drawing, a printed circuit board 100H according to another modified example embodiment may further include a frame 180 having a through-portion H and an insulating material 190 filling at least a portion of the through-portion H, in the printed circuit board 100A according to the above-described example. Furthermore, the first wiring portion 120 may include a plurality of inorganic insulating layers 121, a plurality of first wiring layers 122 respectively disposed on or within the plurality of inorganic insulating layers 121, and a plurality of first wiring vias 123 respectively disposed within the plurality of inorganic insulating layers 121. Additionally, a first wiring layer 122 of the uppermost most, among the plurality of first wiring layers 122, may include a plurality of conductive pads 125, and a cavity C may expose at least a portion of each of the plurality of conductive pads 125, and a surface treatment layer P may be disposed on at least a portion of each of the exposed conductive pads 125. Furthermore, each of the plurality of semiconductor chips 151 and 152 may be connected to one or more of the plurality of conductive pads 125. For example, the printed circuit board 100H according to another modified example embodiment may be a combination of the printed circuit board 100A according to an example embodiment, the printed circuit board 100B according to another modified example embodiment, the printed circuit board 100C according to another modified example embodiment, and the printed circuit board 100E according to another modified example embodiment. Other details may be substantially the same as those described for the printed circuit board 100A according to the above-described example embodiment, the printed circuit board 100B according to the modified example embodiment, the printed circuit board 100C according to another modified example embodiment, and the printed circuit board 100E according to another modified example embodiment.

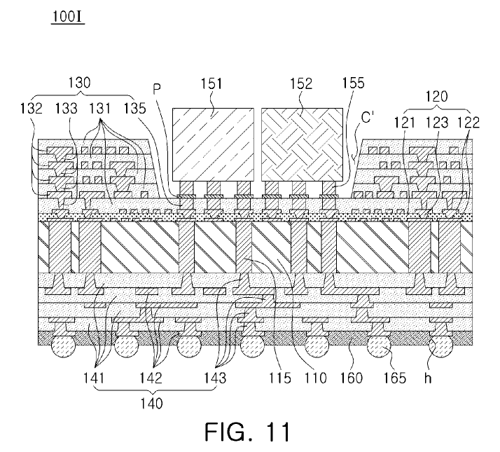

FIG. 11 is a cross-sectional view schematically illustrating another example embodiment of a printed circuit board.

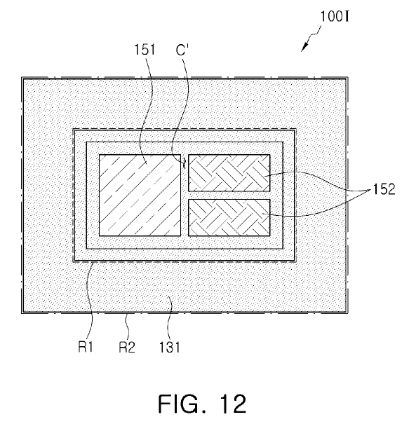

FIG. 12 is a plan view schematically illustrating a top view of the printed circuit board of FIG. 11.

Referring to the drawings, a printed circuit board 100I according to another example embodiment may be configured so that one or more first organic insulating layers 131, for example, each of a plurality of first organic insulating layers 131 may include a non-photosensitive insulating material, in the printed circuit board 100A according to the above-described example embodiment. For example, the one or more first organic insulating layers 131, for example, each of the plurality of first organic insulating layers 131, may include Ajinomoto Build-up Film (ABF). In this case, a wall surface of a cavity C’ formed in the one or more first organic insulating layers 131, for example, the plurality of first organic insulating layers 131, may not have a step portion between layers.

For example, in a printed circuit board 100I according to another example embodiment, in the case in which the one or more first organic insulating layers 131 include the plurality of first organic insulating layers 131, inner surfaces forming wall surfaces of the cavities C’ of first organic insulating layers 131 through which the cavity C’ penetrate, among the plurality of first organic insulating layers 131, may be connected to each other without step portions between layers. For example, a printed circuit board 100I according to another example embodiment may form a second wiring portion 130 based on a plurality of non-photosensitive organic insulating layers, and the cavity C’ may be formed continuously within each non-photosensitive organic insulating layer. Accordingly, wall surfaces of partial cavities formed within each non-photosensitive organic insulating layer may be connected to each other without step portions between layers.

Meanwhile, the cavity C’ may have a substantially tapered shape in which a width of an upper end thereof is wider than a width of a lower end thereof, in cross-section, but the present disclosure is not limited thereto, and if necessary, the cavity C’ may also have a substantially vertical shape. The cavity C’ having such a structure may be more easily formed within the non-photosensitive organic insulating layer, and similarly, a plurality of semiconductor chips 151 and 152 may be more easily mounted within the cavity C’ having such a structure. Other details may be substantially the same as those described for the printed circuit board 100A according to the above-described example embodiment.

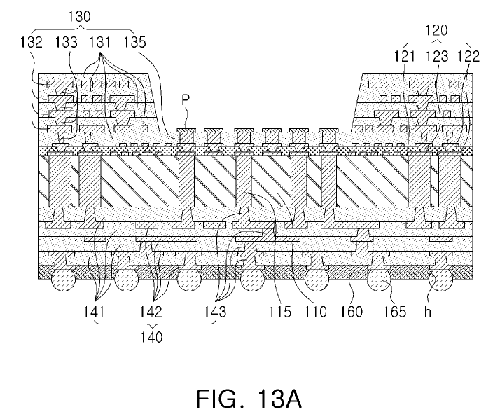

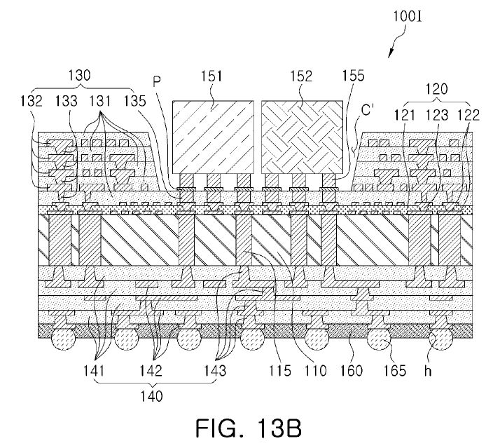

FIGS. 13A and 13B are schematic cross-sectional views illustrating another example embodiment of manufacturing a printed circuit board.

Referring to the drawings, an intermediate structure prior to forming the cavity C’ may be formed through the processes described with reference to FIGS. 3A to 3D, and next, the cavity C’ may be formed in a central region of the second wiring portion 130 on the above-described plane. The cavity C’ may be formed by performing laser processing, chemical etching, and/or plasma etching on the one or more first organic insulating layers 131, for example, the plurality of first organic insulating layers 131. The cavity C’ may be formed up to the stopper layer described above. After forming the cavity C’, the stopper layer may be removed by etching, or the like. Alternatively, the stopper layer described above may not be formed, in which case the stopper layer removal process may be unnecessary. Next, a plurality of semiconductor chips 151 and 152 may be mounted in the cavity C’. The printed circuit board 100I according to another example embodiment described above may be manufactured through a series of processes, but a manufacturing process is not necessarily limited thereto. Other details may be substantially the same as those described in a manufacturing example of the printed circuit board 100A according to the above-described example embodiment.

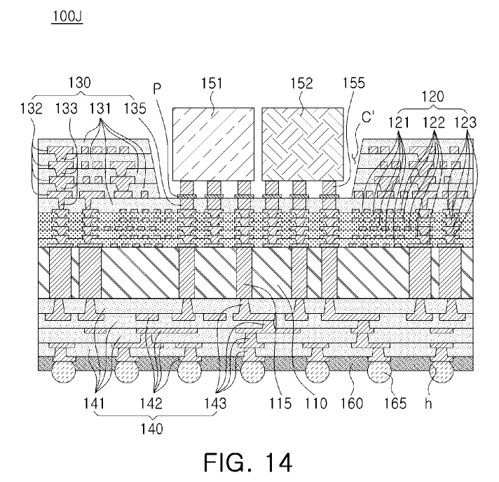

FIG. 14 is a cross-sectional view schematically illustrating a modified example embodiment of a printed circuit board.

Referring to the drawing, a printed circuit board 100J according to a modified example embodiment may include a first wiring portion 120 may include a plurality of inorganic insulating layers 121, a plurality of first wiring layers 122 respectively disposed on or within the plurality of inorganic insulating layers 121, and a plurality of first wiring vias 123 respectively disposed within the plurality of inorganic insulating layers 121, in the printed circuit board 100I according to another example embodiment described above. Other details may be substantially the same as those described for the printed circuit board 100A according to the above-described example embodiment, the printed circuit board 100B according to the modified example embodiment, and the printed circuit board 100I according to another example embodiment.

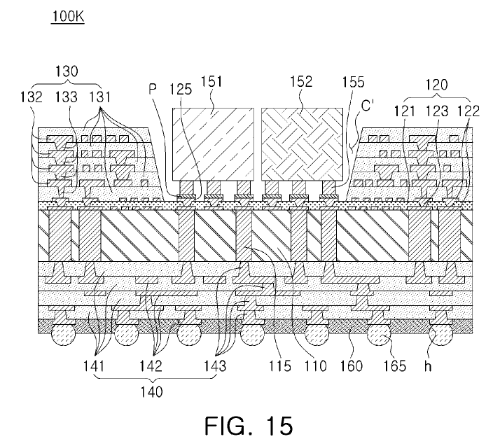

FIG. 15 is a cross-sectional view schematically illustrating another modified example embodiment of a printed circuit board.

Referring to the drawing, a printed circuit board 100K according to another modified example embodiment may be configured so that one or more first wiring layers 122, for example, a first wiring layer 122 of an uppermost layer, among the plurality of first wiring layers 122, may include a plurality of conductive pads 125, in the printed circuit board 100I according to another example embodiment described above, and a cavity C’ may expose at least a portion of each of the plurality of conductive pads 125, and a surface treatment layer P may be disposed on at least a portion of each of the exposed conductive pads 125. Furthermore, each of the plurality of semiconductor chips 151 and 152 may be connected to at least one of the plurality of conductive pads 125. Other details may be substantially the same as those described for the printed circuit board 100A according to the above-described example embodiment, the printed circuit board 100C according to another modified example embodiment, and the printed circuit board 100I according to another modified example embodiment.

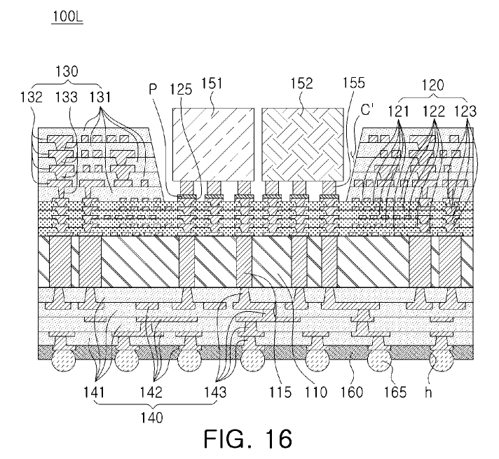

FIG. 16 is a cross-sectional view schematically illustrating another modified example embodiment of a printed circuit board.

Referring to the drawing, a printed circuit board 100L according to another modified example embodiment may be configured so that a first wiring portion 120 may include a plurality of inorganic insulating layers 121, a plurality of first wiring layers 122 respectively disposed on or within the plurality of inorganic insulating layers 121, and a plurality of first wiring vias 123 respectively disposed within the plurality of inorganic insulating layers 121, in the printed circuit board 100I according to the above-described other example. Additionally, a first wiring layer 122 of an uppermost layer, among the plurality of first wiring layers 122, may include a plurality of conductive pads 125, and a cavity C’ may expose at least a portion of each of the plurality of conductive pads 125, and a surface treatment layer P may be disposed on at least a portion of each of the exposed conductive pads 125. Furthermore, each of the plurality of semiconductor chips 151 and 152 may be connected to one or more of the plurality of conductive pads 125. For example, a printed circuit board 100L according to another modified example embodiment may be a combination of the printed circuit board 100I according to another example embodiment, the printed circuit board 100J according to another modified example embodiment, and a printed circuit board 100K according to another modified example embodiment. Other details may be substantially the same as those described for the printed circuit board 100A according to the above-described example embodiment, the printed circuit board 100B according to the modified example embodiment, the printed circuit board 100C according to another modified example embodiment, the printed circuit board 100I according to another modified example embodiment, the printed circuit board 100J according to the modified example embodiment, and the printed circuit board 100K according to another modified example embodiment.

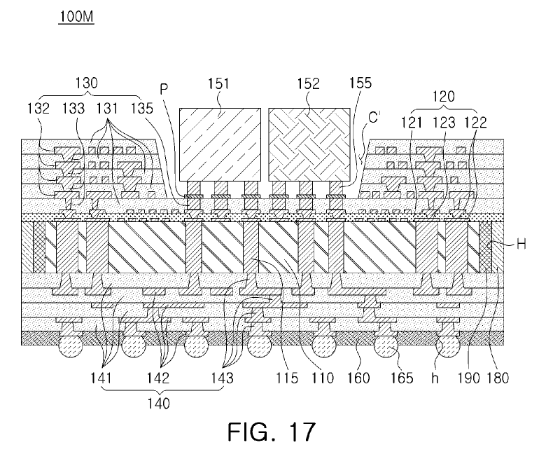

FIG. 17 is a cross-sectional view schematically illustrating another modified example embodiment of a printed circuit board.

Referring to the drawing, a printed circuit board 100M according to another modified example embodiment may further include a frame 180 having a through-portion H and an insulating material 190 filling at least a portion of the through-portion H, in the printed circuit board 100I according to the above-described example embodiment. Other details may be substantially the same as those described for the printed circuit board 100A according to the above-described example embodiment, the printed circuit board 100E according to another modified example embodiment, and the printed circuit board 100I according to another modified example embodiment.

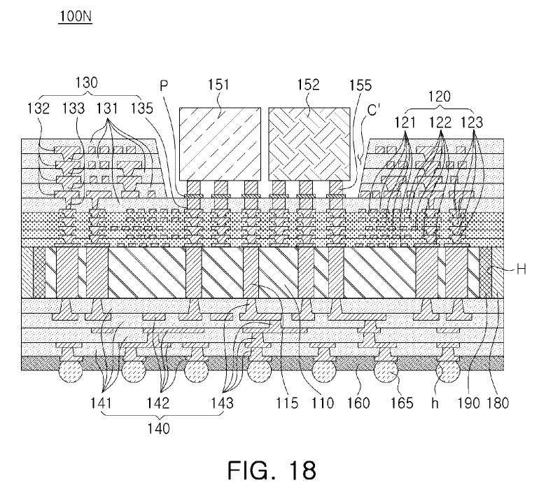

FIG. 18 is a cross-sectional view schematically illustrating another modified example embodiment of the printed circuit board.

Referring to the drawing, a printed circuit board 100N according to another modified example embodiment may further include a frame 180 having a through-portion H and an insulating material 190 filling at least a portion of the through-portion H, in the printed circuit board 100I according to the above-described example embodiment. Additionally, the first wiring portion 120 may include a plurality of inorganic insulating layers 121, a plurality of first wiring layers 122 respectively disposed on or within the plurality of inorganic insulating layers 121, and a plurality of first wiring vias 123 respectively disposed within the plurality of inorganic insulating layers 121. For example, a printed circuit board 100N according to another modified example embodiment may be a combination of the printed circuit board 100I according to another example embodiment, the printed circuit board 100J according to another modified example embodiment, and the printed circuit board 100M according to another modified example embodiment. Other details may be substantially the same as those described for the printed circuit board 100A according to the above-described example embodiment, the printed circuit board 100B according to the modified example embodiment, the printed circuit board 100E according to another modified example embodiment, the printed circuit board 100I according to another modified example embodiment, the printed circuit board 100J according to the modified example embodiment, and the printed circuit board 100M according to another modified example embodiment.

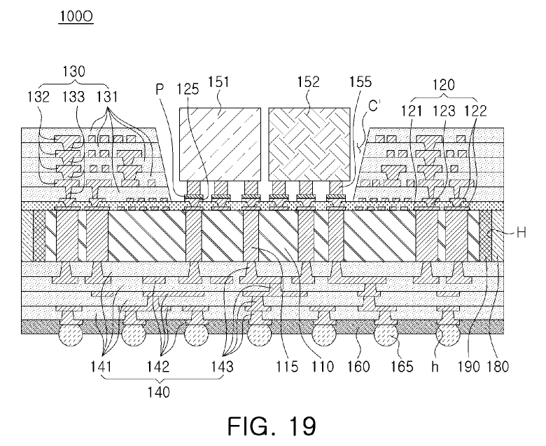

FIG. 19 is a cross-sectional view schematically illustrating another modified example embodiment of a printed circuit board.

Referring to the drawing, a printed circuit board 100O according to another modified example embodiment may further include a frame 180 having a through-portion H and an insulating material 190 filling at least a portion of the through-portion H, in the printed circuit board 100I according to the above-described example embodiment. Additionally, one or more first wiring layers 122, for example, a first wiring layer 122 of an uppermost layer, among the plurality of first wiring layers 122, may include a plurality of conductive pads 125, and a cavity C’ may expose at least a portion of each of the plurality of conductive pads 125, and a surface treatment layer P may be disposed on at least a portion of each of the exposed conductive pads 125. Furthermore, each of a plurality of semiconductor chips 151 and 152 may be connected to one or more of the plurality of conductive pads 125. For example, the printed circuit board 100O according to another modified example embodiment may be a combination of the printed circuit board 100I according to another example embodiment, the printed circuit board 100K according to another modified example embodiment, and the printed circuit board 100M according to another modified example embodiment. Other details may be substantially the same as those described for the printed circuit board 100A according to the above-described example embodiment, the printed circuit board 100C according to another modified example embodiment, the printed circuit board 100E according to another modified example embodiment, the printed circuit board 100I according to another modified example embodiment, the printed circuit board 100K according to another modified example embodiment, and the printed circuit board 100M according to another modified example embodiment.

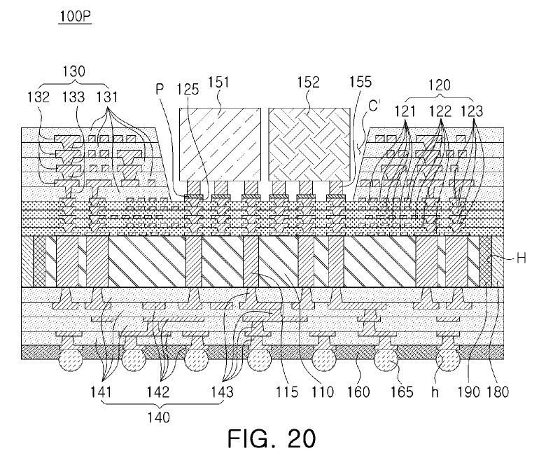

FIG. 20 is a cross-sectional view schematically illustrating another modified example embodiment of a printed circuit board.

Referring to the drawing, a printed circuit board 100P according to another modified example embodiment may further include a frame 180 having a through-portion H and an insulating material 190 filling at least a portion of the through-portion H, in the printed circuit board 100I according to the above-described example embodiment. Additionally, the first wiring portion 120 may include a plurality of inorganic insulating layers 121, a plurality of first wiring layers 122 respectively disposed on or within the plurality of inorganic insulating layers 121, and a plurality of first wiring vias 123 respectively disposed within the plurality of inorganic insulating layers 121. Furthermore, a first wiring layer 122 of an uppermost layer, among the plurality of first wiring layers 122, may include a plurality of conductive pads 125, and a cavity C’ may expose at least a portion of each of the plurality of conductive pads 125, and a surface treatment layer P may be disposed on at least a portion of each of the exposed conductive pads 125. Furthermore, a plurality of semiconductor chips 151 and 152 may each be connected to at least one of the plurality of conductive pads 125. For example, the printed circuit board 100P according to another modified example embodiment may be a combination of the printed circuit board 100I according to another modified example embodiment, the printed circuit board 100J according to another modified example embodiment, the printed circuit board 100K according to another modified example embodiment, and the printed circuit board 100M according to another modified example embodiment. Other details may be substantially the same as those described for the printed circuit board 100A according to the above-described example embodiment, the printed circuit board 100B according to the above-described example embodiment, the printed circuit board 100C according to another modified example embodiment, the printed circuit board 100E according to another modified example embodiment, the printed circuit board 100I according to another modified example embodiment, the printed circuit board 100J according to the above-described example embodiment, the printed circuit board 100K according to the above-described example embodiment, and the printed circuit board 100M according to another modified example embodiment.

In the present disclosure, a thickness, a width, a length, a pitch, a depth and the like, may be measured using a scanning microscope, an optical microscope, or the like, based on a cross-section of a printed circuit board that has been polished or cut, respectively. The cut cross-section may be a vertical cross-section or a horizontal cross-section, and each value may be measured based on a required cut cross-section. If the value is not constant, the value may be determined as an average value of the values measured at five arbitrary points. The width of an upper end and/or a lower end of a via or cavity may be measured on a cross-section taken along a central axis of the via or cavity in a thickness direction of the substrate. The depth of the via or cavity may be measured as a distance from the upper end to the lower end of the via on a cross-section taken along the central axis of the via or cavity in the thickness direction of the substrate.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of approximately filling, and may include, for example, a case in which some pores or voids exist.

In the present disclosure, substantially, determination may be performed by including a process error or a positional deviation occurring in a manufacturing process, and an error during measurement. For example, “substantially identical” in terms of a line width, a gap, a thickness, a height, and the like, may include not only being numerically completely identical, but also having approximately similar numerical values. Furthermore, “substantially having a certain shape” may include not only having that exact shape, but also having approximately that shape. Furthermore, being substantially coplanar may include not only a case in which components exist on the completely same plane, but also a case in which components exist on approximately the same plane.

In the present disclosure, “substantially identical material” may mean not only completely identical materials, but also materials of the same type. For example, the compositions of the materials may be substantially identical, but specific composition ratios thereof may differ slightly.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, a lower side, a lower portion, and a lower surface are used to refer to a downward direction with respect to a cross-section of a drawing, and an upper side, an upper portion, and an upper surface are used to refer to an opposite direction thereof. However, this defines the direction for convenience of explanation, and the scope of the rights of the claims is not particularly limited by the description of such a direction, and the concept of upper and lower portions may be changed at any time.

In the present disclosure, a meaning of being connected is a concept including not only directly connected but also indirectly connected through an adhesive layer or the like. Furthermore, a meaning of electrically connected is a concept including both physically connected and not connected. Additionally, expressions such as first and second are used to distinguish one component from another, and do not limit the order and/or importance of the components. In some cases, a first component may be referred to as a second component without departing from the scope of rights, or similarly, the second component may be referred to as the first component.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
a glass layer;
a first wiring portion disposed on an upper side of the glass layer; and
a second wiring portion disposed on an upper side of the first wiring portion,
wherein the first wiring portion includes one or more inorganic insulating layers, one or more first wiring layers respectively disposed on or within the one or more inorganic insulating layers, and one or more first wiring vias respectively disposed within the one or more inorganic insulating layers, and
the second wiring portion includes one or more first organic insulating layers, one or more second wiring layers respectively disposed on or within the one or more first organic insulating layers, and one or more second wiring vias respectively disposed within the one or more first organic insulating layers, and has a cavity penetrating through at least a portion of the one or more first organic insulating layers.

2. The printed circuit board according to claim 1, wherein each of the one or more inorganic insulating layers includes at least one of a silicon oxide film and a silicon nitride film.

3. The printed circuit board according to claim 1, wherein a thickness of at least one of the one or more inorganic insulating layers is thinner than a thickness of at least one of the one or more first organic insulating layers.

4. The printed circuit board according to claim 1, wherein at least one of the one or more first wiring layers includes a relatively high-density wiring as compared to at least one of the one or more second wiring layers.

5. The printed circuit board according to claim 1, wherein a thickness of at least one of the one or more first wiring layers is thinner than a thickness of at least one of the one or more second wiring layers.

6. The printed circuit board according to claim 1, further comprising:
a third wiring portion disposed on a lower side of the glass layer; and
a through-via penetrating through at least a portion of the glass layer,
wherein the third wiring portion includes one or more second organic insulating layers, one or more third wiring layers respectively disposed on or within the one or more second organic insulating layers, and one or more third wiring vias respectively disposed within the one or more second organic insulating layers.

7. The printed circuit board according to claim 6, wherein a first wiring layer of a lowermost layer, among the one or more first wiring layers, is in direct contact with an upper surface of the glass layer and an upper surface of the through-via, respectively,
a second organic insulating layer of an uppermost layer, among the one or more second organic insulating layers, is disposed between a lower surface of the glass layer and a third wiring layer of an uppermost layer, among the one or more third wiring layers, and
a lower surface of the through-via is connected to at least a portion of the third wiring layer of the uppermost layer, through a third wiring via penetrating through at least a portion of the second organic insulating layer of the uppermost layer, among the one or more third wiring vias.

8. The printed circuit board according to claim 6, wherein the one or more first wiring layers, the one or more second wiring layers, and the one or more third wiring layers include a plurality of first wiring layers, a plurality of second wiring layers, and a plurality of third wiring layers, respectively.

9. The printed circuit board according to claim 8, wherein the one or more inorganic insulating layers is one inorganic insulating layer, and
the one or more first organic insulating layers and the one or more second organic insulating layers include a plurality of first organic insulating layers and a plurality of second organic insulating layers, respectively.

10. The printed circuit board according to claim 8, wherein the one or more inorganic insulating layers include a plurality of inorganic insulating layers, and
the one or more first organic insulating layers and the one or more second organic insulating layers include a plurality of first organic insulating layers and a plurality of second organic insulating layers, respectively.

11. The printed circuit board according to claim 8, wherein the one or more first wiring vias, the one or more second wiring vias, and the one or more third wiring vias include a plurality of first wiring vias, a plurality of second wiring vias, and a plurality of third wiring vias, respectively, and
the plurality of first wiring vias connect the plurality of first wiring layers, some of the plurality of second wiring vias connect the plurality of first and second wiring layers to each other, other portions of the plurality of second wiring vias connect the plurality of second wiring layers to each other, some of the plurality of third wiring vias connect the through-via and the plurality of third wiring layers to each other, and other portions of the plurality of third wiring vias connect the plurality of third wiring layers to each other.

12. The printed circuit board according to claim 6, further comprising:
a frame having a through-portion; and
an insulating material disposed in at least a portion of the through-portion,
wherein at least a portion of the glass layer is disposed within the through-portion;
the insulating material is disposed between the frame and the glass layer;
the one or more inorganic insulating layers cover an upper surface of the glass layer, an upper surface of the frame, and an upper surface of the insulating material, respectively; and
the one or more second organic insulating layers cover a lower surface of the glass layer, a lower surface of the frame, and a lower surface of the insulating material, respectively.

13. The printed circuit board according to claim 6, further comprising:
a solder resist layer disposed on a lower side of the third wiring portion; and
electrical connection metals disposed in openings of the solder resist layer to connected to one of the one or more third wiring layers.

14. The printed circuit board according to claim 1, wherein the second wiring portion further includes a plurality of conductive bumps respectively penetrating through at least a portion of at least one of the one or more first organic insulating layers,
the cavity exposes at least a portion of each of the plurality of conductive bumps from the one or more first organic insulating layers,
a surface treatment layer is disposed on at least a portion of each of the plurality of conductive bumps.

15. The printed circuit board according to claim 14, further comprising:
a plurality of semiconductor chips, each of which is at least partially disposed within the cavity and connected to one or more of the plurality of conductive bumps.

16. The printed circuit board according to claim 1, wherein a first wiring layer of an uppermost layer, among the one or more first wiring layers, includes a plurality of conductive pads,
the cavity exposes at least a portion of each of the plurality of conductive pads from the one or more first organic insulating layers, and
a surface treatment layer is disposed on at least a portion exposed in each of the plurality of conductive pads.

17. The printed circuit board according to claim 16, further comprising:
a plurality of semiconductor chips, each of which is at least partially disposed within the cavity and connected to at least one of the plurality of conductive pads.

18. The printed circuit board according to claim 1, wherein the one or more first organic insulating layers include a plurality of first organic insulating layers,
each of the plurality of first organic insulating layers includes a photosensitive insulating material,
the cavity penetrates through at least a portion of the plurality of first organic insulating layers, and
inner surfaces of the first organic insulating layers through which the cavity penetrates have a step portion between layers.

19. The printed circuit board according to claim 1, wherein the one or more first organic insulating layers include a plurality of first organic insulating layers,
each of the plurality of first organic insulating layers includes a non-photosensitive insulating material,
the cavity penetrates through at least a portion of the plurality of first organic insulating layers, and
inner surfaces of the first organic insulating layers through which the cavity penetrates are connected to each other without a step portion between layers.

20. A printed circuit board, comprising:
a glass layer;
a first substrate portion disposed on an upper side of the glass layer; and
a second substrate portion disposed on an upper side of the first substrate portion, the second substrate portion including a first region having a cavity and a second region surrounding the first region,
wherein the first substrate portion includes a first insulating body including an inorganic insulating material and one or more first conductive pattern layers respectively disposed on or within the first insulating body,
the second wiring portion includes a second insulating body including an organic insulating material and one or more second conductive pattern layers respectively disposed on or within the second insulating body, and
the one or more second conductive pattern layers are disposed in the second region.

21. The printed circuit board according to claim 20, wherein each of the one or more first conductive pattern layers includes a plurality of line patterns, and
the plurality of line patterns have a line width, a gap and a thickness of 3 μm or less.

22. The printed circuit board according to claim 20, wherein the second substrate portion further includes a plurality of conductive bumps, each of which is at least partially disposed within the second insulating body,
the plurality of conductive bumps are disposed in the first region, and
the cavity partially penetrates through an upper surface of the second insulating body, and exposes at least a portion of each of the plurality of conductive bumps from the second insulating body.

23. The printed circuit board according to claim 20, wherein the one or more first conductive pattern layers includes a plurality of conductive pads,
the plurality of conductive pads are disposed in the first region, and
the cavity penetrates from an upper surface to a lower surface of the second insulating body, and exposes at least a portion of each of the plurality of conductive pads from the second insulating body.

24. The printed circuit board according to claim 20, wherein the one or more second conductive pattern layers include one or more of a capacitor pattern, an inductor pattern and a dummy pattern.

25. The printed circuit board according to claim 20, further comprising:
a third substrate portion disposed on a lower side of the glass layer; and
a through-via penetrating through at least a portion of the glass layer,
wherein the third wiring portion includes a third insulating body including an organic insulating material and one or more third conductive pattern layers respectively disposed on or within the third insulating body.

26. The printed circuit board according to claim 25, further comprising:
a frame having a through-portion; and
an insulating material disposed in at least a portion of the through-portion,
wherein at least a portion of the glass layer is disposed within the through-portion;
the insulating material is disposed between the frame and the glass layer;
the first insulating body covers an upper surface of the glass layer, an upper surface of the frame, and an upper surface of the insulating material, respectively, and
the third insulating body covers a lower surface of the glass layer, a lower surface of the frame and a lower surface of the insulating material, respectively.
